(19) United States
(12) Patent Application Publication
(10) Pub. No.: US 2021/0408399 A1
(43) Pub. Date: Dec. 30, 2021

(54) HYBRID ORGANIC-INORGANIC PEROVSKITE-STRUCTURED CRYSTALS AS ELECTRO-OPTIC MATERIALS

(71) Applicants: Sjoerd HOOGLAND, Toronto (CA); Grant William WALTERS, Toronto (CA); Yuan GAO, Toronto (CA); Edward Hartley SARGENT, Toronto (CA)

(72) Inventors: Sjoerd HOOGLAND, Toronto (CA); Grant William WALTERS, Toronto (CA); Yuan GAO, Toronto (CA); Edward Hartley SARGENT, Toronto (CA)

(73) Assignee: Huawei Technologies Canada Co., Ltd., Kanata (CA)

(21) Appl. No.: 17/067,213

(22) Filed: Oct. 9, 2020

Related U.S. Application Data
(60) Provisional application No. 63/044,883, filed on Jun. 26, 2020.

(51) Int. Cl. H01L 51/00

(52) U.S. Cl. CPC H01L 51/0077; H01G 9/2009

(57) ABSTRACT

A class of crystals comprises an inorganic lattice in which organic molecules are embedded, thereby allowing macroscopic electro-optic responsiveness. The lattice is based on a metal halide perovskite structure. The organic molecules can be with an intrinsic dipole such that when aligned and fixed in place in the inorganic lattice, they induce electro-optic responsiveness in the macroscopic crystal. Alternatively, their mere presence in the structure can induce sufficient polarity in the scaffold itself for a similar responsiveness. The molecules themselves can comprise a carbon backbone that is completely conductive, partially conductive, or non-conductive, as well as zero, one or two functional groups that allow binding to the lattice and increased polarity.

### CROSS-REFERENCE TO RELATED APPLICATIONS

This application claims the benefit of priority to U.S. Patent Application Ser. No. 63/044,883, entitled “HYBRID ORGANIC-INORGANIC PEROVSKITE-STRUCTURED CRYSTALS AS ELECTRO-OPTIC MATERIALS” filed Jun. 26, 2020, which is hereby incorporated by reference in its entirety.

### FIELD OF THE INVENTION

This invention pertains generally to the field of electro-optic materials and in particular to a particular crystal structure that exhibits improved electro-optic effects, and in particular a higher electro-optic coefficient.

### BACKGROUND OF THE INVENTION

Conventional on-chip optical modulators are manufactured using silicon p-n junctions. These modulators are able to provide the speed and modulation depths required for silicon photonics applications. However, p-n junction based modulators can often exhibit high optical losses and typically require a large footprint. Alternative materials and devices are available, but they come with their own limitations. In particular, organic electro-optic materials could provide all of the required performance characteristics, but they lose their performance due to material instability. Other materials include inorganic crystals such as LiNbO₃, but this class exhibits limited ability to be integrated into silicon photonics architectures.

Therefore, there is a need for a material that can obviate or mitigate one or more limitations of the prior art by exhibiting the speed and modulation depths required for silicon photonics applications, low optical losses, stability under standard operating conditions, and compatibility with silicon photonics architectures, particularly in that they could enable small-footprint modulators on silicon photonics chips.

This background information is provided to reveal information believed by the applicant to be of possible relevance to the present invention. No admission is necessarily intended, nor should be construed, that any of the preceding information constitutes prior art against the present invention.

### SUMMARY OF THE INVENTION

The current invention pertains to a new class of materials that can combine the stability of inorganic materials with the high electro-optic (EO) performance of certain organic materials having the ability to integrate with silicon photonics chips. The new EO material has the ability to provide high efficiencies, thereby allowing a smaller footprint of photonics chips.

Similarly to organic EO materials, the EO response of the new organic-inorganic EO materials is provided by acceptor and donor groups on the carbon backbone of a molecule. This backbone can be anchored inside a perovskite structure. In some embodiments, a 2.5 dimensional perovskite structure is used. In some embodiments a two-dimensional (2D) perovskite structure may be used. The combination of the stability of the inorganic perovskite scaffold and the design of the EO molecule inside the perovskite can yield a stable, high-efficiency performance of the new materials.

Some embodiments can incorporate organic molecules in which the organic molecules are designed to be functional to induce a large macroscopic dipole moment in the perovskite crystal.

Further, in embodiments of the present invention, a ligand to bind an organic molecule to the scaffold can be designed, but not necessarily, to be non-centrosymmetric facilitating a large inherent dipole and a correspondingly large EO response. The design of a ligand and its dipole-generating functional groups has the constraint that it needs to be able to fit within the inorganic scaffold. The rational design of ligands for these purposes has also not been reported.

The following embodiments describe different configurations and designs for the hybrid molecule-embedded, perovskite-structured crystals.

### BRIEF DESCRIPTION OF THE DRAWINGS

FIG. 1 illustrates an embodiment of an inorganic perovskite-structured scaffold in which organic molecules, each having two functional groups, have been embedded. Each molecule is oriented such that its longitudinal polarization is parallel to the a-axis.

FIG. 2 illustrates an embodiment of an inorganic perovskite-structured scaffold in which organic molecules, each having one functional group, have been embedded. Each molecule is oriented such that its longitudinal polarization is parallel to the a-axis.

FIG. 3 illustrates an embodiment of an inorganic perovskite-structured scaffold in which organic molecules, each having two functional groups, have been embedded. The molecules are oriented such that approximately half of them have their longitudinal polarization parallel to the a-axis, approximately half of them have their longitudinal polarization anti-parallel to the a-axis, and each of these two orientations is uniformly distributed, cancelling out any macroscopic dipole along the a-axis. Further, because each side group points in the same direction along the c-axis, a polarization is created approximately along the c-axis.

FIG. 4 illustrates an embodiment of an inorganic perovskite-structured scaffold in which organic molecules, each having one functional group, have been embedded. The molecules are oriented such that approximately half of them have their longitudinal polarization parallel to the a-axis, approximately half of them have their longitudinal polarization anti-parallel to the a-axis, and each of these two orientations is uniformly distributed, cancelling out any macroscopic dipole along the a-axis. Further, because each side group points in the same direction along the c-axis, a polarization is created approximately along the c-axis.

FIG. 5 illustrates an embodiment of an inorganic perovskite-structured crystal in which organic molecules have been embedded. The molecules are aligned in a same orientation and induce a distortion of the atomic alignments inside the inorganic layer of the perovskite-structured crystal. The distortions of atomic displacements do not rely on molecular dipoles, but they can be enhanced by the molecular side groups.

FIG. 6A illustrates an organic molecule containing an acceptor functional group and a donor functional group.

FIG. 6B illustrates a scenario where acceptor-donor molecules are not anchored in a scaffold, and undergo spontaneous reorientation when net polarization is reduced.

FIG. 6C shows a configuration in which an acceptor-donor molecule is anchored within a perovskite scaffold.

FIG. 6D illustrates three different organic molecules in accordance with embodiments of the present invention.

FIG. 7A illustrates one embodiment of a hybrid material comprising the lattice structure of PbBr₄ with incorporated organic molecules of the present invention.

FIG. 7B illustrates one embodiment of a hybrid material comprising the lattice structure of PbBr₄ with incorporated organic molecules of the present invention, from another perspective.

FIG. 7C illustrates x-ray diffraction spectra of samples, according to an embodiment of the present invention.

FIG. 7D is an x-ray diffraction spectrum in a range of temperatures, for a sample embodiment of the present invention.

FIG. 8A illustrates an embodiment of the present invention, as represented by density functional theory calculation software.

FIG. 8B illustrates the same embodiment as FIG. 8A, but viewed from another perspective.

FIG. 8C illustrates another embodiment of the present invention, as represented by density functional theory calculation software.

FIG. 8D illustrates yet another embodiment of the present invention, as represented by density functional theory calculation software.

FIG. 9 is a table showing theoretical Berry phase polarization values for the embodiments of FIGS. 8A, 8B, 8C, and 8D.

FIG. 10 illustrates an optical set-up used to measure electro-optic coefficients of a sample crystal.

FIG. 11 is a graph displaying the effects of poling on the electro-optic coefficient of a hybrid material in accordance with one embodiment of the present invention.

FIG. 12 is a graph displaying the effects of applying a modulated voltage on an embodiment sample. The result is expressed as a voltage generated by a photodetector measuring a polarized 1.55 micron beam, transmitted through the sample.

### DETAILED DESCRIPTION OF THE INVENTION

Embodiments of the present invention entail a new class of closely related, high performance electro-optic (EO) materials with optical losses that are sufficiently low that the EO materials can be used to enable small-footprint modulators on silicon photonics chips. The materials combine the high EO performance of organic molecules with the stability of inorganic materials.

In embodiments of the present invention, the EO response of organic-inorganic EO materials is provided by acceptor and donor groups on the carbon backbone of a molecule. This backbone is anchored inside a reduced-dimensional perovskite-structured crystal. A reduced-dimensional perovskite-structured crystal is one that contains layers of an inorganic scaffold, as well as layers of organic material. When two layers of organic material are separated by a single layer of perovskite octahedra, the structure is identified as “2D”. When however, two layers of organic material are separated by N layers of perovskite octahedra, where N>1, the structure is identified as “2.5D”. In some embodiments a 2.5D perovskite-structured crystal can be used. In some embodiments a 2D perovskite-structured crystal can be used. The combination of the stability of the inorganic perovskite scaffold and the design of the EO molecule inside the perovskite can yield a stable, high-efficiency performance of the new materials.

In embodiments of the present invention, the hybrid organic-inorganic EO materials are based on 2.5D metal halide perovskite-structured crystals. These materials can have a layered structure consisting of inorganic layers separated by organic ligands. The inorganic layers can act like quantum wells, where the width of the wells can be tuned by adjusting the thickness of each inorganic layer. This can be used to tune the bandgap of light-emitting and light-harvesting 2.5D perovskite materials. The ligand molecules can be modified to tune the separation of the inorganic layers, which can enable cross-talk between the inorganic layers and the conductivity of the hybrid material.

In embodiments of the present invention, a ligand can be designed to have the functionality of a large inherent dipole that facilitates a large non-centrosymmetry and a correspondingly large EO response. The design of a ligand and its dipole-generating functional groups has the constraint that it needs to be able to fit within the inorganic scaffold.

In embodiments of the present invention, inorganic EO materials are engineered to facilitate a large EO response by incorporating organic EO materials within. For organic EO materials to induce an EO response on the macroscopic level, the molecules are required to be co-aligned in some manner. In purely organic EO materials, the molecules easily lose their alignment, thereby reducing the EO performance. In the hybrid EO materials of the present invention however, the inorganic scaffold ensures strong binding of the molecules, preventing the molecules from losing their alignment and thereby preserving the EO performance.

The design of the molecules can involve functional groups that can both bind to the inorganic layers and create a large dipole moment to facilitate a large EO response. This versatility can allow the hybrid architecture to be optimized to reach the performance levels of the organic molecules. The materials can be processed from a solution, thereby allowing easy integration with modulator structures on silicon photonics chips. This is in contrast with other inorganic EO materials, practically all off which require growth at high temperature and are therefore not easily compatible with on-chip applications.

The hybrid 2.5D materials in embodiments of the present invention are semiconductors whose optoelectronic properties can be engineered to exhibit low optical losses at standard communication wavelengths. Since they do not require doping, the optical propagation losses can be much lower than those of p-n junctions made from silicon.

The following embodiments describe different configurations and designs for the hybrid molecule-embedded, perovskite-structured crystals.

In a first set of embodiments, organic molecules are designed to contain acceptor and donor functional groups that can facilitate a dipole. An acceptor functional group can be any of a number of different functional groups that would be known and understood in the art, including any one of a halide, —CF₃, —COOH, —CN, and —NO₂. A donor functional group can be any of a number of different functional groups that would be known and understood in the art, including any one of —OH, —OR, and —C₆H₅. An organic molecule from this set of embodiments can be designed to be able to conduct electrons and holes along its carbon backbone. Those skilled in the art will appreciate that the selection or design of an organic molecule can be done so that a desired low level of resistance is created, allowing for the conduction of electrons and holes without incurring sufficient loss. In some embodiments, this is accomplished by having the backbone composed of unsaturated carbon-carbon bonds (C—C) and benzene rings. The functional groups can be placed on either end of the backbone thereby facilitating a large dipole moment approximately parallel to the backbone. The molecules can have an ammonium group on either end, which can provide anchoring to an inorganic layer of the layered perovskite structure. The molecules can then form a separating layer between any two successive inorganic perovskite layers. The perovskite-structured material can be a metal-halide arranged in a perovskite structure and in particular, it can be a lead-halide with a perovskite structure.

In some embodiments, the molecules can be aligned in the crystal structure such that the dipole of each molecule is oriented in the same direction as the dipole of the other molecules in the same layer. This can be accomplished for example by placing the molecules inside the perovskite structure such that all donor groups of a same layer of molecules are on one side of an inorganic layer, and all acceptor groups of another layer of molecules are on the opposite side of the same inorganic layer, or vice versa. A macroscopic crystal can be built up of these inorganic-organic-inorganic layers. For the dipole moment of a macroscopic crystal to be maximized, all molecules on all layers can be parallel and oriented in a same direction.

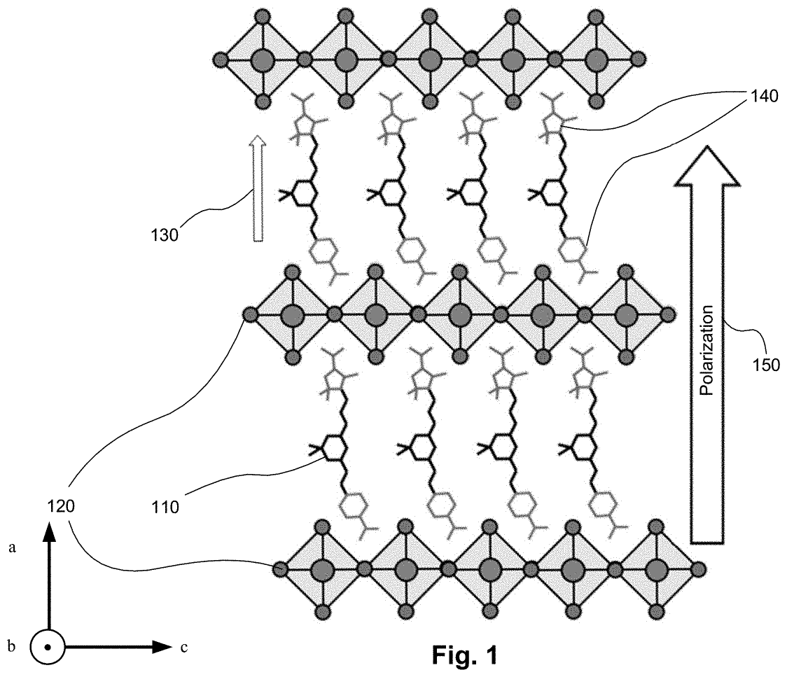

FIG. 1 illustrates an embodiment where a layered perovskite-structured crystal can densely pack and orient organic molecules 110 by anchoring them to its inorganic lattice 120. In this embodiment, each molecule contains a large dipole 130 along the backbone of the molecule. A dipole is induced by the acceptor and donor functional groups 140 that are present on either end of each molecule. The molecules 110 are aligned in an ordered fashion such that all dipoles point in a same direction. In FIG. 1, the dipoles are aligned along, or parallel to, the backbone of each molecule, and they induce a macroscopic polarization 150 for the entire crystal.

In embodiments represented by FIG. 1, the dipoles 130 are induced by both acceptor and donor groups 140, which are far apart and separated by a conductive backbone. This spacing apart of the acceptor and donor functional groups can provide the highest possible magnitude for a dipole moment in the given molecule. All molecules are aligned with their dipoles pointing in a same direction along the backbones, which gives rise to the largest dipole moment 150 on the macroscopic scale. Therefore, these embodiments represent a design for maximizing the electro-optic effect sought from a hybrid organic-inorganic perovskite-structured crystal.

In a second set of embodiments, an embedded organic molecule can be designed to contain, instead of both an acceptor functional group and a donor functional group, either one or the other, and this can also facilitate a dipole. An acceptor functional group can be any of a number of different functional groups that would be known and understood in the art, including any one of a halide, —CF₃, —COOH, —CN, and —NO₂. A donor functional group can be any of a number of different functional groups that would be known and understood in the art, including any one of —OH, —OR, and —C₆H₅. A molecule of these embodiments is designed to be able to conduct electrons and holes along its backbone. This can be accomplished by having the backbone being composed of unsaturated C—C bonds and benzene rings. The functional group of choice is placed on one end of the backbone, thereby facilitating a large dipole moment. A molecule can have on either end an ammonium group, which can provide anchoring to an inorganic layer of a perovskite-structured crystal. A collection of molecules can then form a layer separating any two layers of an inorganic perovskite-structured crystal. The perovskite-structured material can be a metal-halide perovskite-structured material, and in particular, a lead-halide perovskite-structured material.

In such further embodiments, the molecules can be aligned in the crystal structure such as to ensure that the dipole of each molecule is oriented in the same direction. This can be accomplished for example by placing the molecules inside the perovskite structure such that all acceptor or donor functional groups are on a same side of an inorganic layer. A macroscopic crystal can be built up of such alternating inorganic and organic layers. For the dipole moment of a macroscopic crystal to be maximized, all molecules on all layers can be parallel and oriented in a same direction.

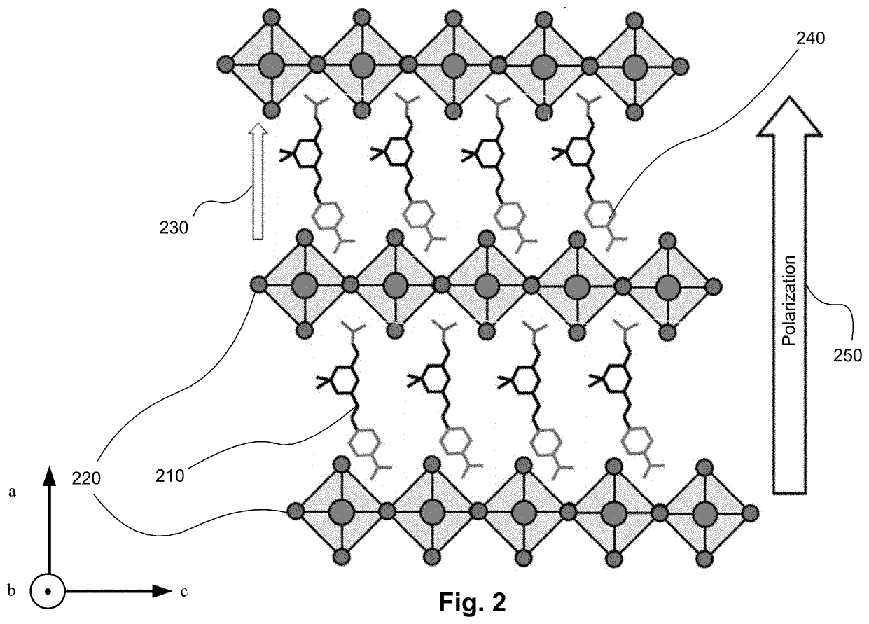

FIG. 2 illustrates embodiments of the second set, where a layered perovskite-structured crystal can densely pack and orient organic molecules 210 by anchoring them to its inorganic lattice 220. In these embodiments, each molecule has a large dipole 230 along the backbone of the molecule. A dipole is induced by one of an acceptor function group and a donor functional group 240 present on one end of each molecule. The molecules are aligned in an ordered fashion so that all dipoles point in a same direction. In FIG. 2, the dipoles are aligned along each molecule, and they induce a polarization 250 for the entire perovskite-structured crystal. It will be understood that in a manufacturing process, it may not be possible for 100% of the dipoles to be arranged in parallel with the other dipoles, and substantially complete alignment is sufficient.

In embodiments that can be represented by FIG. 2, each dipole 230 is induced by a single functional group 240. Since the backbone of organic molecule 210 is conductive, there is still a possibility for a large dipole moment to be induced by the molecule, but it can be weaker than in some other embodiments. All molecules can be aligned such that all dipoles point in approximately the same direction along their backbones, which can give rise to a correspondingly large macroscopic dipole moment 250. It will be understood that in a manufacturing process, it may not be possible for 100% of the dipoles to be arranged in parallel with the other dipoles, and substantially complete alignment is sufficient.

In a third set of embodiments, an organic molecule is designed to contain both an acceptor and a donor functional group, such as to facilitate a dipole in a direction approximately parallel to the inorganic molecule layers, instead of a direction approximately perpendicular to the inorganic molecule layers. An acceptor functional group can be any of a number of different functional groups that would be known and understood in the art, including any one of a halide, —CF₃, —COOH, —CN, and —NO₂. A donor functional group can be any of a number of different functional groups that would be known and understood in the art, including any one of —OH, —OR, and —C₆H₅. A functional group can be placed at a certain position of the backbone of the organic molecule. The backbone between two functional groups is can to be able to conduct electrons and holes. This can be accomplished by using unsaturated C—C bonds and benzene rings. The rest of the backbone, that is the sections of the backbone that are not between the two functional groups, can include non-conductive segments. The organic molecules can have an ammonium group on either end to facilitate anchoring to an inorganic layer of a perovskite structure. The organic molecules can then form a separating layer between any adjacent inorganic perovskite layers. The perovskite material can comprise a metal-halide perovskite structure and in particular, it can comprise a lead-halide perovskite structure.

In the third set of embodiments, the organic molecules are aligned with each other in the crystal structure, but the functional groups can be randomly organized inside the structure. In this way, the dipole moment of one organic molecule is cancelled by the dipole moment of a molecule having its functional groups in the opposite direction. Effectively, the functional groups of one type are aligned on one side of a molecule backbone, and the functional groups of the other type are aligned on the opposite side of the molecule backbone. In this way, a dipole moment is induced in the plane of, or parallel to, the organic layer instead of being perpendicular. For a macroscopic perovskite-structured crystal to exhibit a dipole moment, all of its layers have to contain organic molecules, each one having a functional group aligned in one direction of the layer plane, and another functional group aligned in the other opposite direction of the layer plane.

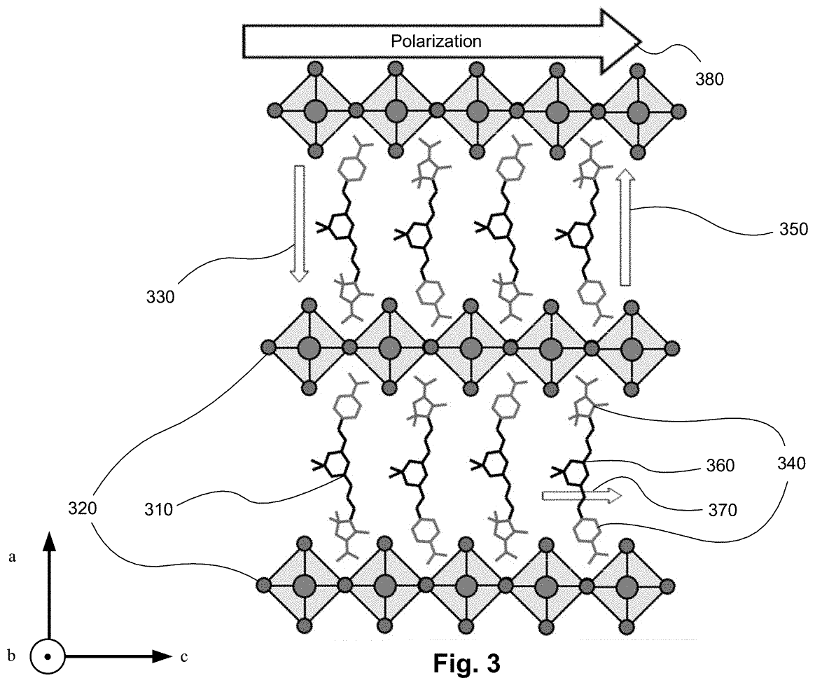

FIG. 3 illustrates an embodiment where a layered perovskite-structured crystal can densely pack and orient organic molecules 310 by anchoring them to its inorganic lattice 320. In embodiments represented by FIG. 3, an organic molecule can have a large dipole 330 along its carbon backbone. A dipole is induced by the acceptor and donor functional groups 340 that are present on either end of each organic molecule. However, in the a-axis of the crystal, the organic molecules are randomly oriented in either one of two orientations, such that some molecules have their dipole point to one end 330 of the crystal, and others to the opposing end 350 of the crystal. This creates a net-zero dipole in the direction of the organic molecules and the crystal's a-axis. In these embodiments, the functional groups of the organic molecules are aligned in an in-plane direction, such as the c-axis, with all donors 360 pointing to one in-plane direction, and all acceptor groups 340 pointing in the opposing in-plane direction. This induces a net dipole moment in a direction along the planes. In FIG. 3, the donors 360 are aligned on the left side of the backbone and the acceptors 340 on the right side, thereby inducing a polarization 370 towards the right, or parallel to the c-axis. A parallel macroscopic polarization 380 is thereby induced.

An embodiment representable by FIG. 3 is an alternative version to an efficient design described above. It can be difficult to control the orientation of molecules inside a layered perovskite-structured crystal. For example, certain molecules might stack with their dipole randomly pointing up or down. Alternatively, in a single layer, the dipoles might be oriented one way, but in the next layer, they might be oriented the opposite way. All these configurations can result in a macroscopic dipole moment that is very low. This illustrated embodiment does not require reliance upon vertical alignment of the dipoles. Instead, there is a horizontal, in-plane alignment instead. This can be much better controlled even after the crystal has been grown, by heating it to approximately its glass-transition temperature in the presence of a large electric field. The electric field will force the functional groups to align along the field, and after cooling, the crystal's molecules will be frozen in the preferred configuration.

In embodiments represented by FIG. 3, a dipole is induced between a donor and acceptor that are situated at some place along the carbon backbone and separated by a conductive part. This can ensure that the magnitude of the macroscopic dipole is significant.

In a fourth set of embodiments, an organic molecule is designed to contain only one of either an acceptor functional group, or a donor functional group, so as to facilitate a dipole in a direction along the layered planes. An acceptor functional group can be any of a number of different functional groups that would be known and understood in the art, including any one of a halide, —CF₃, —COOH, —CN, and —NO₂. A donor functional group can be any of a number of different functional groups that would be known and understood in the art, including any one of —OH, —OR, and —C₆H₅. A functional group is placed at a certain position along the carbon backbone of the organic molecule. The part of the backbone that contains the functional group preferably contains a conductive element. For example, in a preferred embodiment, a functional group is attached to a benzene ring that is part of the backbone. This can ensure a sufficiently strong dipole moment. The rest of the backbone can be made of conductive elements such as unsaturated C—C bonds and benzene rings, and/or non-conductive parts. An organic molecule can have an ammonium group on either end to provide anchoring to the inorganic layer of the 2.5D perovskite structure. The organic molecules can then form a separating layer between any two adjacent inorganic layers of the perovskite structure. The perovskite material can be a metal-halide perovskite-structured crystal and in particular, a lead-halide perovskite-structured crystal.

In these embodiments, the organic molecules are aligned in the crystal structure, but their functional groups are randomly oriented along the structure's plane-perpendicular direction. In this way, the dipole moment of one molecule is cancelled by the dipole moment of a neighboring molecule having a functional group in the opposite direction. Instead, all functional groups are aligned on one side of the molecule backbone. In this way, a dipole moment in the plane of the organic layers is induced. For the macroscopic crystal to exhibit a dipole moment, all of the perovskite layers have to contain organic molecules where the functional groups are aligned in one direction in the plane of the layers.

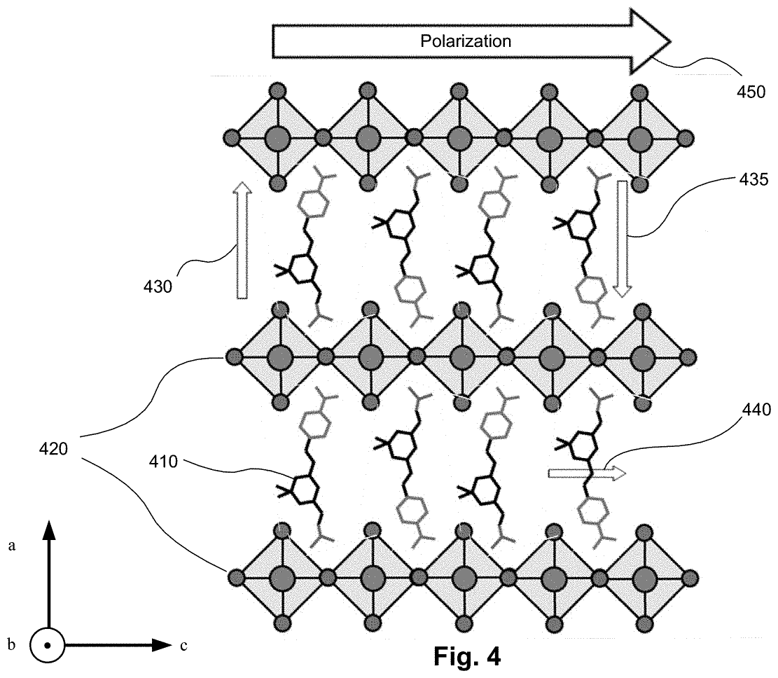

FIG. 4 illustrates a layered perovskite-structured crystal that can densely pack and orient organic molecules 410 by anchoring them to its inorganic lattice 420. In these embodiments, an organic molecule can contain a large dipole 430 along its carbon backbone. The dipole 430 can be induced by a functional group present on one end of the molecule. In these embodiments, the functional groups are either all donors, or all acceptors. However, the molecules are randomly oriented along the a-axis or the plane-perpendicular (vertical) direction of the crystal, such that some approximately half of the molecules have their dipole oriented to one end 430 of the perovskite crystal and others oriented to the other end of the crystal 435. This creates a net-zero dipole along the a-axis (vertical) direction. In these embodiments, the functional group is aligned in a horizontal (in-plane) direction with all functional groups aligned in one horizontal direction, such as the c-axis. This induces a net dipole moment 440 in the horizontal plane. In FIG. 4, the acceptors are all on the right side of the backbone, thereby inducing a macroscopic polarization 450 towards the right.

Embodiments of the fourth set are similar to those of the third set, except that the functional groups are only one of either donors or acceptors. Having both donors and acceptors can create a steric hindrance to fit the molecules inside the perovskite crystal. There are some design tools to avoid steric hindrances, such as the composition of the inorganic perovskite crystal. However, using only one functional group can also provide a design tool for the organic molecules to fit within the perovskite scaffold.

In a fifth set of embodiments, an organic molecule is used to create a distortion of the arrangement of the atoms in the inorganic part of the perovskite layer. In these embodiments, a molecule does not necessarily need to have a conductive backbone. Further, the molecule does not necessarily have to be non-centrosymmetric. Its effect however can be enhanced with non-centrosymmetry, by adding to it one or more acceptor and/or donor functional groups. Whether the resulting molecule is centrosymmetric or not, the added functional groups can induce a slight atomic displacement in the inorganic part of the perovskite structure. In addition, non-centrosymmetry in a molecule can also be created by the molecule's mere orientation inside the crystal. For a dipole moment to be significant on the macroscopic scale, these displacements need to be all aligned in a same orientation. This can require all the molecules to be ordered in one same orientation.

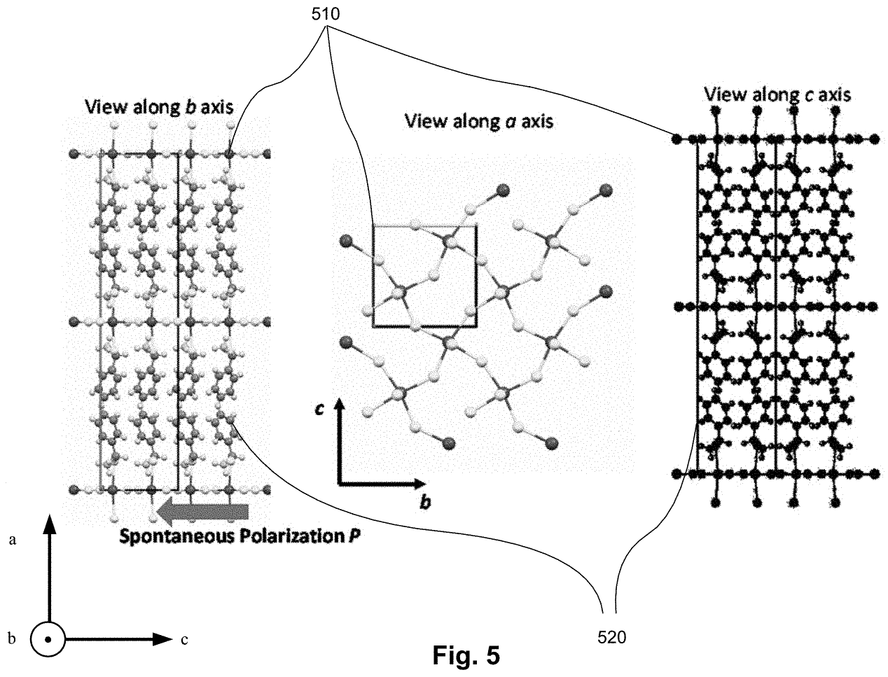

FIG. 5 illustrates a layered perovskite-structured crystal 510 that can densely pack and orient organic molecules 520 by anchoring them to its inorganic lattice 510. The organic molecules can be packed in a dense, aligned fashion within the layered crystal, and the orientation of a molecule inside the crystal can induce a displacement of atoms of the inorganic layers 510, whether the molecule is centrosymmetric or not. The scaffold's atomic displacements result in an overall non-centrosymmetry and spontaneous polarization, thereby allowing macroscopic electro-optic effects in the crystal as a whole.

The fifth set of embodiments rely less on the functional groups of the organic molecules, but more so on the displacement of the atoms inside the inorganic layers of the perovskite structure. In these embodiments, the overall non-centrosymmetry can come from the organic molecule backbone itself and therefore does not necessarily need to rely on a special design and synthesis of the functional group attachments to the molecules or an intrinsic molecular dipole. This makes the synthesis of the molecule and ultimately the final material, much simpler. Typically, the induced atomic displacement is quite small, which results in small dipole moments and hence a small macroscopic electro-optic effect.

Embodiments of the present invention can be materialized with single-crystal growth methods and organic compound synthesis methods that are known in the art and detailed in the enclosed appendix which forms part of this application.

Embodiments of the present invention can be used in devices and instruments that rely on similar electro-optic, polarized and polarizable materials, including semiconductors, photovoltaics, light-emitting diodes, laser sources, and photodetectors.

In embodiments of the present invention, non-centrosymmetric organic molecules with an intrinsic dipole, once incorporated in the crystal structure, can be aligned by heating the crystal near its glass-transition temperature, and applying an electric field to it. This process can also induce and enhance a polarization in the crystal scaffold itself.

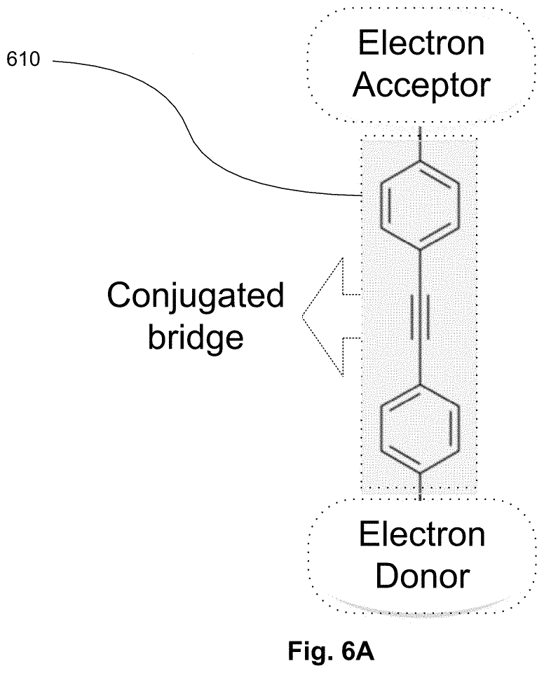

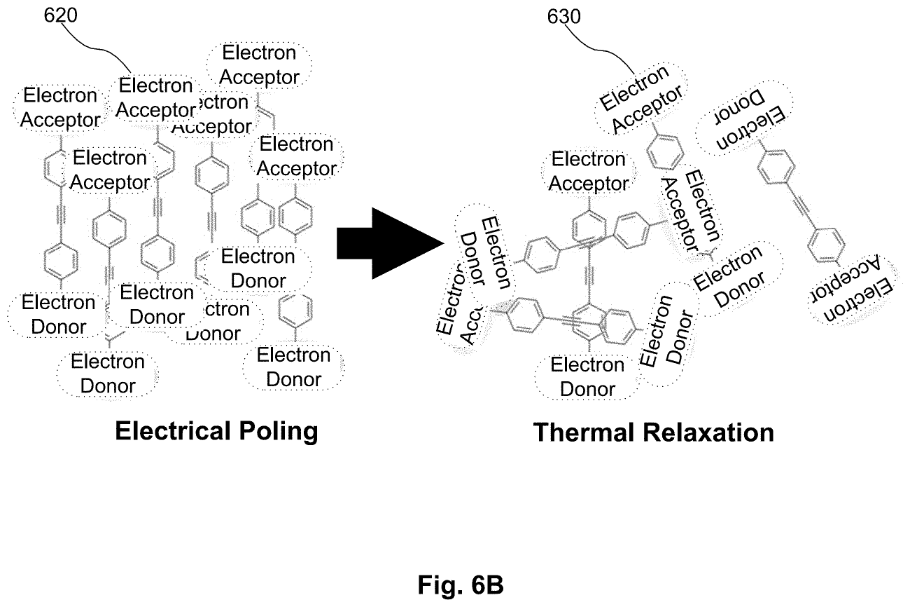

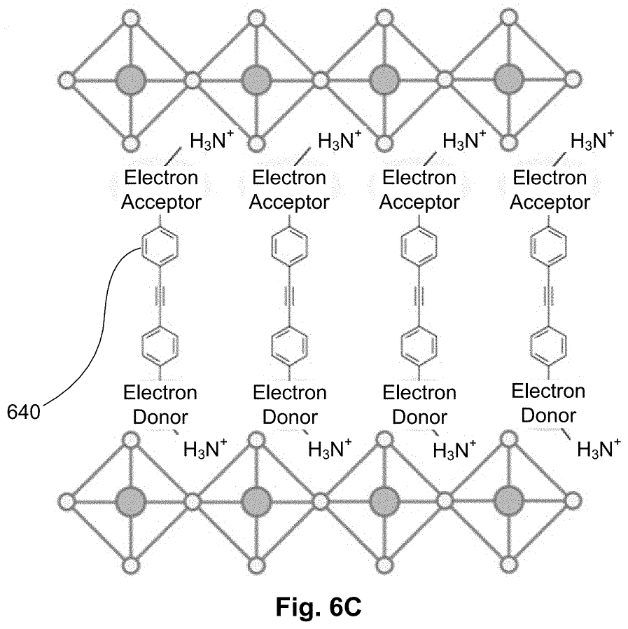

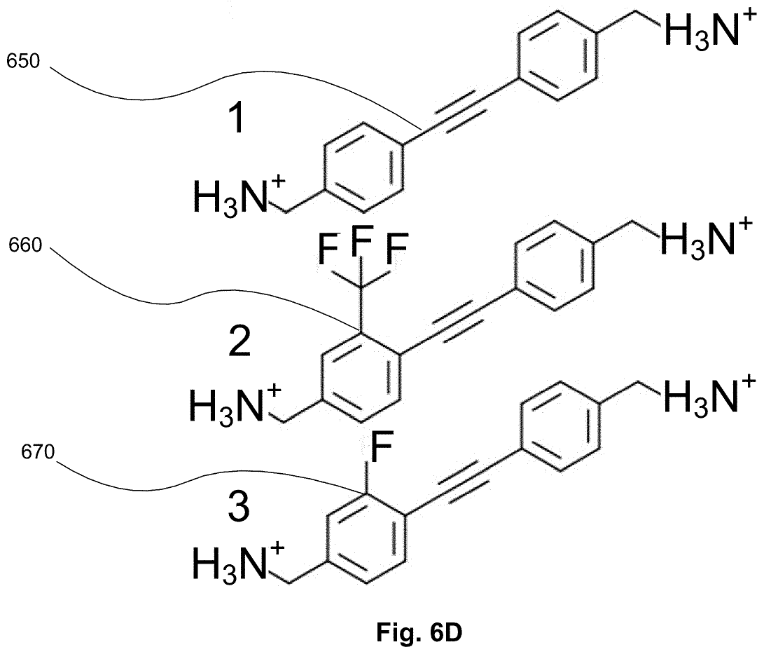

FIG. 6A illustrates one embodiment of an organic molecule 610 with an electron donor on one end and an electron acceptor on the other end.

FIG. 6B illustrates a plurality of organic molecules 610. When polarized with application of an electric field without a crystal scaffold 620, the organic molecules will align; however, the organic molecules tend to undergo thermal relaxation 630 once the electric field is removed.

FIG. 6C however, illustrates how a scaffold can prevent such disorganisation 640 upon removal of the field.

FIG. 6D illustrates a variety of organic molecules, each designed to have different functional groups. Centrosymmetric molecule 650 does not have an inherent dipole. Attachment of a polar functional group, such as a trifluoromethyl group, to produce molecule 660, or a fluoro group, to produce molecule 670, at or near one end can provide the resulting organic molecule with an inherent dipole. It was observed that incorporation of the bulkier trifluoromethyl group led to steric interactions between adjacent molecules, causing poor alignment of the organic molecules within the crystal lattice. Incorporation of the smaller fluoro group produced an organic molecule with a suitable dipole that fit properly in the crystal lattice without compromising its integrity.

In one embodiment of a hybrid material of the present invention, the inorganic perovskite-structured crystal is PbBr₄, which can be synthesized with conventional single-crystal growth techniques, and characterized with x-ray crystallography techniques.

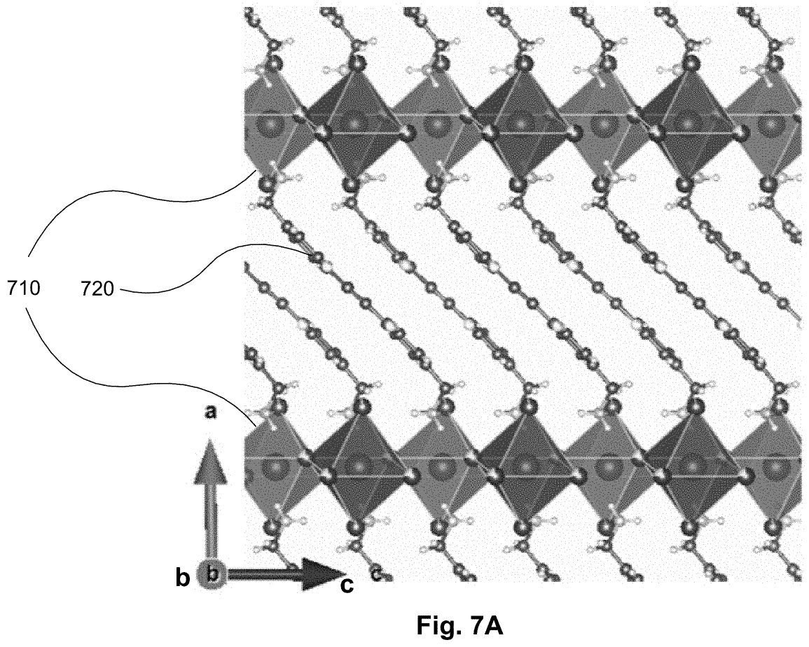

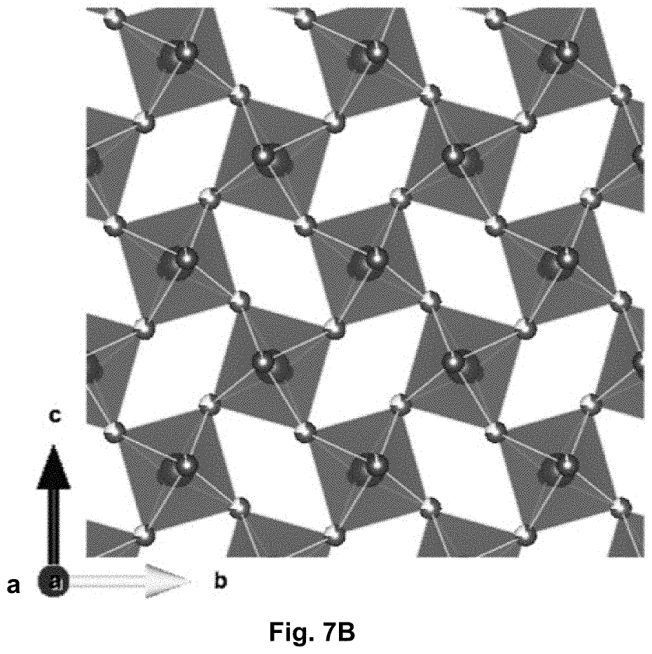

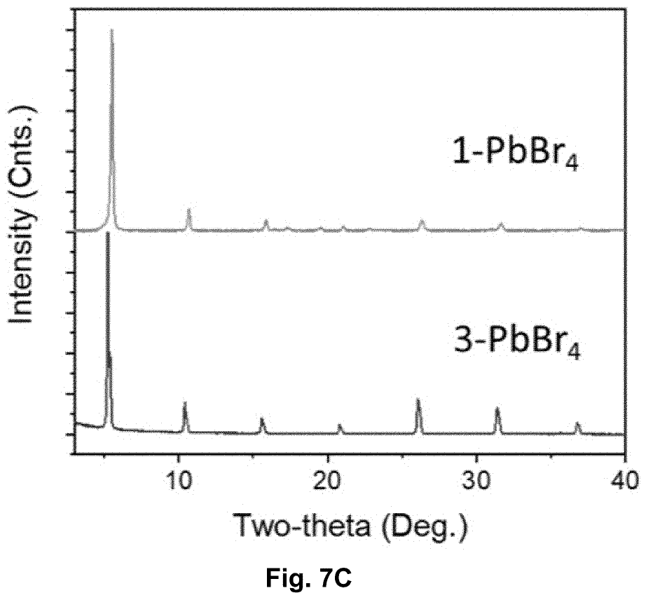

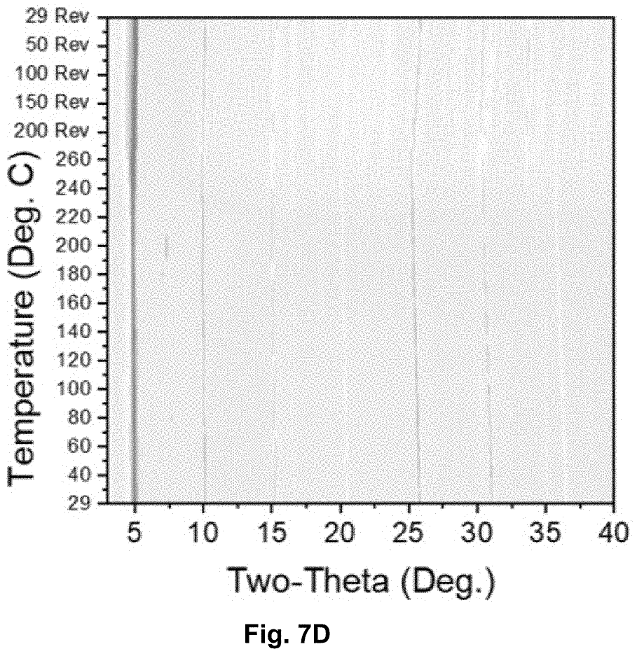

FIG. 7A illustrates a hybrid material in accordance with the present invention, comprising the lattice structure 710 of PbBr₄ with an organic molecule 720 of the present invention incorporated between inorganic crystal layers, as viewed parallel to the molecule layer plane (b-axis).

FIG. 7B illustrates the same hybrid material as in FIG. 7A, but viewed perpendicular to the layer plane (a-axis), instead of parallel.

FIG. 7C illustrates x-ray diffraction data for the hybrid material sample. In particular, FIG. 7C displays the result of beam intensity (vertical axis) as a function of beam direction (horizontal axis), and shows characteristic crystalline peaks.

FIG. 7D also displays the result of beam intensity (darker shade) as a function of beam direction (horizontal axis) and sample temperature (vertical axis). It shows that crystalline peaks are maintained in a cycle of up to at least 270 degrees centigrade, thereby confirming material stability up to such temperatures.

The Berry phase polarization for different configurations of the present invention can be calculated using density functional theory (DFT).

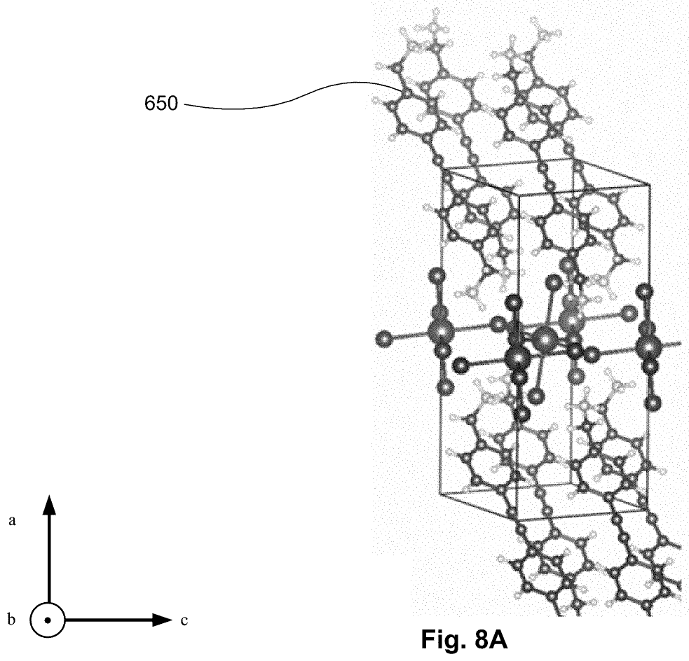

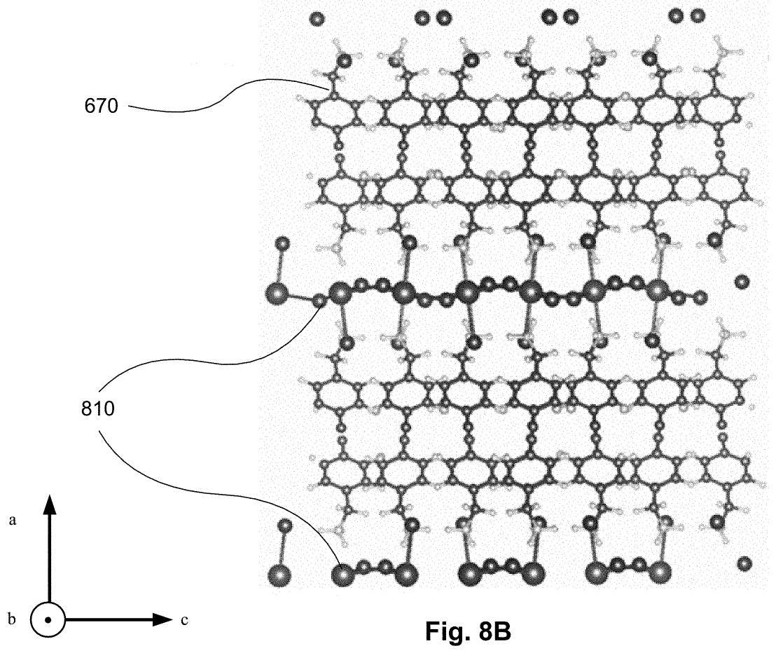

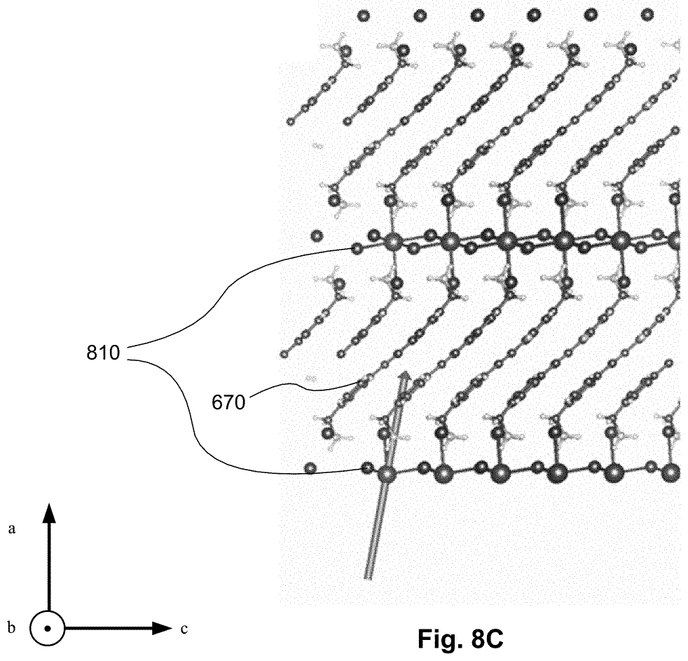

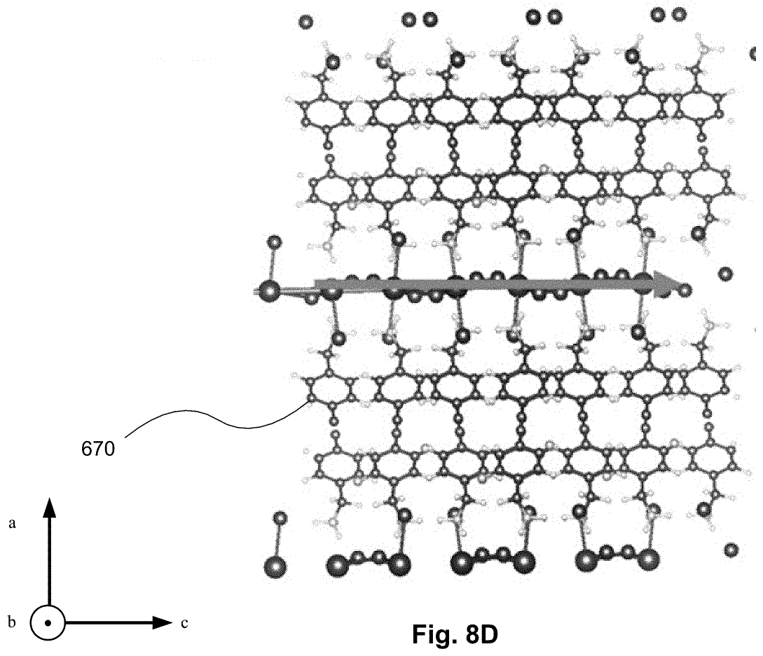

FIG. 8A shows an embodiment of the present invention, as represented by DFT calculation software. It illustrates a structure containing vertically aligned non-polar molecules having functional groups to facilitate binding at both ends. These are molecules 650. Because each of these molecules 650 is non-polar along its backbone length, the magnitude of a resultant dipole arrow can be small and its direction difficult to predict.

FIG. 8B shows a structure containing vertically aligned molecules that are randomly oriented in that the carbon backbones of the organic molecules are all perpendicular to the layers 810, but the positions of functional groups are random. Here, the embedded molecule is 670.

FIG. 8C shows molecules 670 oriented such that their functional groups are aligned to induce dipoles in a direction approximately perpendicularly to the layers 810.

FIG. 8D shows molecules 670 oriented such that their functional groups are aligned to induce dipoles in a direction approximately parallel to the layers. Because each of these molecules 670 is polar along its backbone length, the magnitude of a resultant dipole arrow can be larger than with molecules 650 and its direction better aligned with the layers' perpendicular.

When the molecules are aligned to have their backbone dipoles all pointing approximately along the a-axis, the macroscopic polarization is approximately along the a-axis as well, as shown in FIG. 8C. When however, the molecules have their backbone dipoles oriented along the c-axis, then the macroscopic polarization is also along the c-axis, as in FIG. 8D. Configurations 8A and 8B, where molecules have respectively no intrinsic dipole, and a randomly oriented dipole along the a-axis, can also induce a macroscopic polarization, but a much smaller one, caused at least in part to displacement of the lattice atoms.

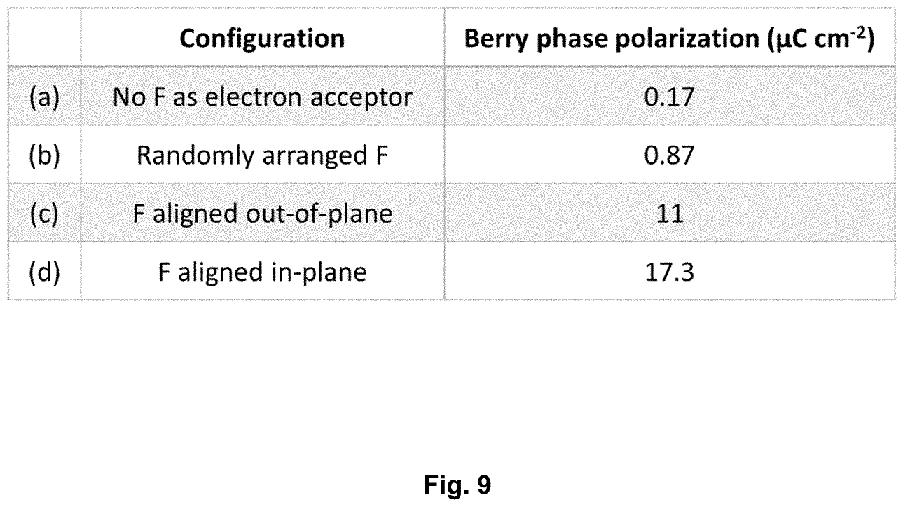

FIG. 9 is a tabular summary of the Berry phase polarization value in units of μC-cm⁻², for embodiments of FIGS. 8A, 8B, 8C and 8D, as calculated with DFT. It can be seen that molecule alignment as in (c) and (d), corresponding to FIGS. 8C and 8D respectively, significantly increases the polarization, as compared with centrosymmetry, (a) or FIGS. 8A, 9A, and with random dipole orientation along the layers' perpendicular, (b) or FIG. 8B.

The hybrid materials of the present invention can be analysed optically. In particular, the intensity of a polarized beam, transmitted through an embodiment of a hybrid crystal, are measured as a function of voltage modulation frequencies applied to a crystal sample, yielding a relative result for an EO coefficient along the direction perpendicular to the planes r₃₁ and an EO coefficient parallel to the planes r₃₃.

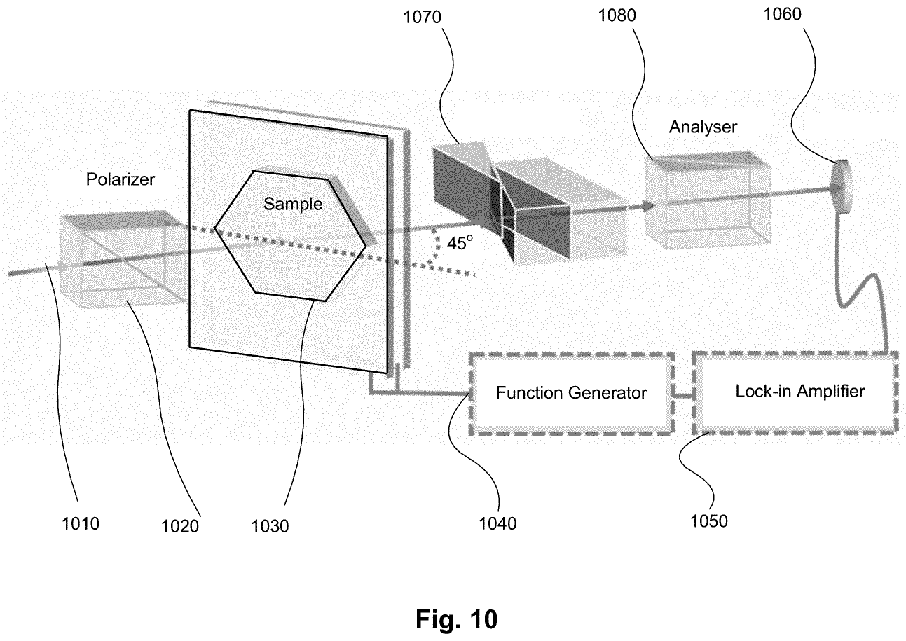

FIG. 10 illustrates an optical set-up used to measure electro-optic coefficients of a sample crystal. A beam 1010 to which the sample is transparent is polarized by a first polarizer 1020 and directed to the sample crystal 1030. A modulated voltage bias is applied to the crystal by a function generator 1040 and a lock-in amplifier 1050 coordinates a detector 1060 to read only incident signals with the modulation frequency, so as to filter out any other unrelated signal noise in the room. The beam is directed to a compensator 1070 for continuous retardance of the beam, and a second polarizer 1080, which is used as a polarization analyzer to allow the detector's observation of the biased crystal's effect on the polarized beam.

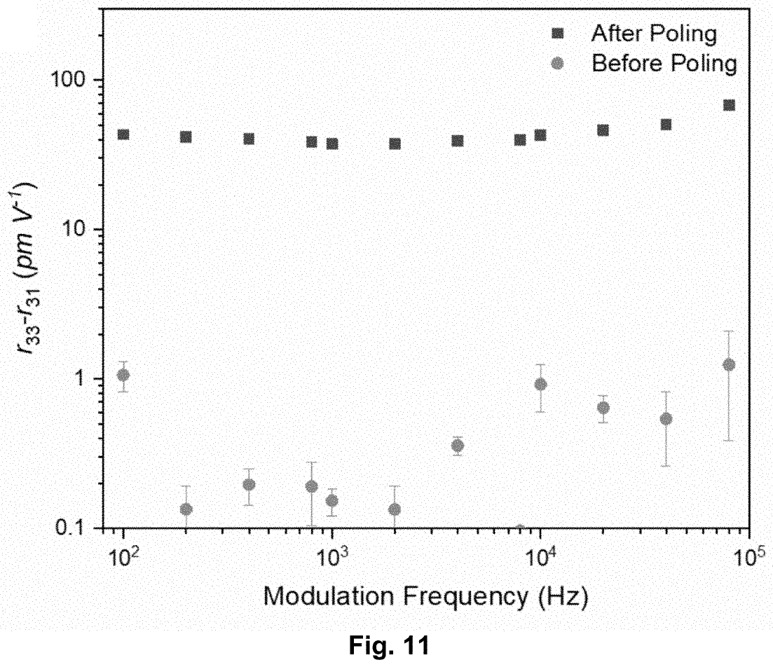

FIG. 11 is a graph displaying results obtained with a sample embodiment using the optical setup of FIG. 10. It can be seen that the EO coefficient, as depicted as the difference between the r₃₃ and r₃₁ response, is much greater when the sample crystal has been poled with a large bias near the material's glass temperature, than the EO coefficient before poling, when all dipoles are randomly oriented. Further, the EO effect is similar within a narrow margin, for frequencies from 100 Hz to 100 000 Hz.

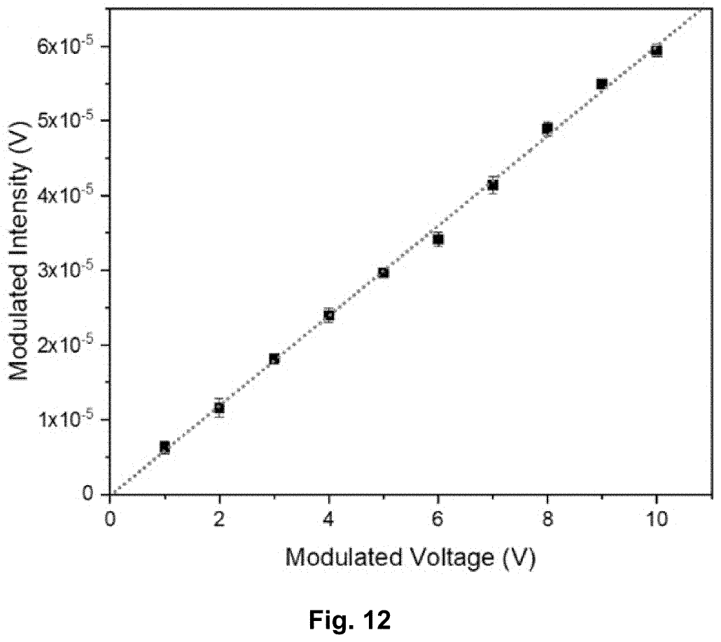

FIG. 12 is a graph displaying the effects of applying a modulated voltage on an embodiment sample. The result is expressed as a voltage generated by a photodetector measuring a polarized beam with a wavelength of 1.55 micron, transmitted through the sample.

A 2.5D perovskite crystal can be used for a variety of applications including light emission and photovoltaics. In light emission applications, an organic molecule can be used as a spacer layer to separate inorganic layers acting as quantum wells. In photovoltaics, the 2.5D perovskites are used for passivation purposes. However, for both of these applications, the layers of the 2.5D perovskite have to be thin because conductivity is very low in the direction perpendicular to the layers. Utilizing conductive backbones increase the conductivity of the materials. As stated, in some embodiments 2D perovskites can be used.

The functional groups discussed can also be used to fine tune the emission properties of a hybrid 2.5D perovskite-structured crystal.

An aspect of the invention provides a crystalline material. Such a crystalline material includes M layers of a crystalline inorganic material, and N layers of organic molecules in which the organic molecules are aligned relative to the layers of inorganic material to form a crystalline structure, with each layer of organic molecules adjacent to at least one of the layers of the crystalline inorganic material such that the crystalline material is electro-optic responsive. In some embodiments the crystalline inorganic material comprises a perovskite-structured lattice. In some embodiments lattice positions of the perovskite-structured lattice are occupied by metals and halides. In some embodiments the crystalline material comprises an organo-lead trihalide perovskite-structured lattice. In some embodiments the crystalline material comprises a reduced dimensional organo-lead trihalide perovskite-structured lattice. In some embodiments the aligned organic molecules are bonded to the inorganic layers and form bridges between inorganic layers. In some embodiments an organic molecule comprises a primary chain of carbon atoms. In some embodiments the organic molecules comprise organic molecules with an intrinsic dipole. In some embodiments the organic molecules with an intrinsic dipole induce atomic displacements in the inorganic layers, thereby inducing observable macroscopic electro-optic responsiveness in the crystalline material. In some embodiments a chain of carbon atoms contains electrically conductive bonds. In some embodiments the organic layers are electrically polarized in a direction approximately perpendicular to the layers of the crystalline material. In some embodiments the organic layers are electrically polarized in a direction approximately parallel to the layers of the crystalline material. In some embodiments an organic molecule contains at least one functional group contributing to: binding the molecule to a layer of the crystalline inorganic material, and enhancing the intrinsic dipole of the molecule. In some embodiments a functional group is an electron donor. In some embodiments a functional group is an electron acceptor. In some embodiments the organic molecules comprise organic molecules without an intrinsic dipole. In some embodiments the organic molecules without an intrinsic dipole induce atomic displacements in the inorganic layers, thereby inducing observable macroscopic electro-optic responsiveness in the crystalline material. In some embodiments N is less than M the first plurality. In some embodiments the organic molecules are aligned perpendicular to the layers of inorganic material. In some embodiments the organic molecules are aligned at about 30 or 45 degrees to the layers of inorganic material.

The crystals of the present invention, are crystalline in that they can have any degree of crystallinity which can be determined with conventional x-ray crystallography techniques. It is not required that a crystalline structure be without defects such as, but not limited to vacancies, slip defects, or the presence of polycrystals. For further clarity, defects do not disqualify a structure of the present invention from being considered to be crystalline.

Embodiments of the present invention mention electro-optics, but other applications where macroscopic electro-optic responsivity is important can also benefit from the new class of materials. These applications include those making use of piezoelectricity and ferroelectricity.

Embodiments have been described above in conjunctions with aspects of the present invention upon which they can be implemented. Those skilled in the art will appreciate that embodiments may be implemented in conjunction with the aspect with which they are described, but may also be implemented with other embodiments of that aspect. When embodiments are mutually exclusive, or are otherwise incompatible with each other, it will be apparent to those skilled in the art. Some embodiments may be described in relation to one aspect, but may also be applicable to other aspects, as will be apparent to those of skill in the art.

Although the present invention has been described with reference to specific features and embodiments thereof, it is evident that various modifications and combinations can be made thereto without departing from the invention. The specification and drawings are, accordingly, to be regarded simply as an illustration of the invention as defined by the appended claims, and are contemplated to cover any and all modifications, variations, combinations or equivalents that fall within the scope of the present invention.

1. A crystalline organo-lead trihalide perovskite-structured lattice material comprising:
M layers of a crystalline inorganic material, wherein M is at least 2 and the crystalline inorganic material comprises a lead halide perovskite-structured lattice, wherein the halide is bromine, and
N layers of organic molecules in which the organic molecules are aligned relative to the layers of inorganic material to form a crystalline structure, wherein N is less than M and wherein the organic molecules comprise organic diammonium molecules containing at least one functional group that is an electron donor or an electron acceptor to provide an intrinsic dipole,
with each layer of organic molecules adjacent to at least one of the layers of the crystalline inorganic material such that the crystalline material is electro-optic responsive.

2. (canceled)

3. The crystalline material of claim 1, wherein lattice positions of the perovskite-structured lattice are occupied by metals and halides.

4. (canceled)

5. The crystalline material of claim 1, wherein the crystalline material comprises a reduced dimensional organo-lead trihalide perovskite-structured lattice.

6. The crystalline material of claim 1, wherein the aligned organic molecules are bonded to the inorganic layers and form bridges between inorganic layers.

7. The crystalline material of claim 1, wherein an organic molecule comprises a primary chain of carbon atoms.

8. (canceled)

9. The crystalline material of claim 1, wherein the organic molecules with an intrinsic dipole induce atomic displacements in the inorganic layers, thereby inducing observable macroscopic electro-optic responsiveness in the crystalline material.

10. The crystalline material of claim 1, wherein a chain of carbon atoms contains electrically conductive bonds.

11. The crystalline material of claim 1, wherein the organic layers are electrically polarized in a direction approximately perpendicular to the layers of the crystalline material.

12. The crystalline material of claim 1, wherein the organic layers are electrically polarized in a direction approximately parallel to the layers of the crystalline material.

13. The crystalline material of claim 1, wherein the organic molecule containing at least one functional group contributes to:
binding the molecule to a layer of the crystalline inorganic material, and
enhancing the intrinsic dipole of the molecule.

14. The crystalline material of claim 13, wherein the functional group is an electron donor.

15. The crystalline material of claim 13, wherein the functional group is an electron acceptor.

16. The crystalline material of claim 1, wherein the organic molecules comprise organic molecules without an intrinsic dipole.

17. The crystalline material of claim 16, wherein the organic molecules without an intrinsic dipole induce atomic displacements in the inorganic layers, thereby inducing observable macroscopic electro-optic responsiveness in the crystalline material.

18. (canceled)

19. The crystalline material of claim 1, wherein the organic molecules are aligned perpendicular to the layers of inorganic material.

20. The crystalline material of claim 1, wherein the organic molecules are aligned at about 30 or 45 degrees to the layers of inorganic material.
